(19) United States
(12) Patent Application Publication
(10) Pub. No.: US 2026/0044086 A1
(43) Pub. Date: Feb. 12, 2026

(54) MASK, MASK STITCHING METHOD AND EXPOSURE METHOD

(71) Applicant: WUHAN XINXIN SEMICONDUCTOR MANUFACTURING CO., LTD., Wuhan (CN)

(72) Inventors: Peng ZHANG, Wuhan (CN); Yan WANG, Wuhan (CN); Sheng HU, Wuhan (CN); Zilu YE, Wuhan (CN); Guanghengwei ZHU, Wuhan (CN); Guoliang YE, Wuhan (CN)

(21) Appl. No.: 19/266,944

(22) Filed: Jul. 11, 2025

(30) Foreign Application Priority Data
Aug. 6, 2024 (CN) 202411067577.4

(51) Int. Cl. G03F 7/00; G03F 1/82

(52) U.S. Cl. CPC G03F 7/70475; G03F 1/82; G03F 7/70466

(57) ABSTRACT

The present invention provides a mask, a mask stitching method and an exposure method. The mask includes a substrate, in which a first pattern is defined in a first direction and a second pattern in a second direction thereof. The first pattern is adapted for exposure of first-directional regions of the overhang, and the second pattern is adapted for exposure of second-directional regions of the overhang. With this arrangement, the overhang of the interposer can be exposed using a single mask, reducing photolithographic cost. In addition, as use of fewer masks is made possible, less effort and time is required by mask pickup. This reduces the time required by photolithographic processing, enabling more efficient photolithographic processing at even lower cost.

### CROSS-REFERENCES TO RELATED APPLICATION

This application claims the priority of Chinese patent application number 202411067577.4, filed on Aug. 6, 2024 and entitled “MASK, MASK STITCHING METHOD AND EXPOSURE METHOD”, the entire contents of which are incorporated herein by reference.

### TECHNICAL FIELD

The present invention relates to the field of semiconductor technology and, in particular, to a mask, a mask stitching method and an exposure method.

### BACKGROUND

With the development of artificial intelligence (AI), 5G, big data, cloud computing and other emerging industries, advanced chip packages are becoming more and more popular, increasing the demand for interposers with high bandwidth, low power consumption and high interconnection density. Limited by a maximum exposure field size of a photolithography tool (e.g., 26 mm×33 mm), i.e., a maximum mask size (e.g., 26 mm×33 mm), fabricating a larger die necessitates the use of stitching, a technique to divide a pattern to be used to make the larger die into segments and expose it segment-by-segment. Further, in order to allow an interposer to support more dies, an overhang may be added thereto to expand its support area.

The overhang can provide physical support, and optionally route electrical connection, to dies to be wired up on the interposer. Therefore, it may be necessary to expose the overhang, including all its X- and Y-directional regions, to remove any unwanted metal layer therefrom. However, limited by a maximum mask size, such overhang exposure tends to require stitching of multiple masks, typically four in the state of the art, greatly increasing the mask cost. Further, even the currently most advanced photolithography tools are equipped with only two reticle pods, because the simultaneous use of more than two masks will dramatically reduce the number of wafers that can be processed per hour (WPH). This poses additional limitation on overhang exposure.

On the other hand, if any metal layer in the overhang remains untreated, it may give rise to issues in subsequent processing, such as cracking during dicing or damage to the manufacturing equipment. Therefore, how to remove a metal layer from an overhang remains a problem requiring urgent attention.

### SUMMARY

It is an object of the present invention to overcome the problem that conventional overhang exposure requires use of multiple masks, which leads to increased photolithographic cost, by presenting a mask, a mask stitching method and an exposure method.

To this end, the present invention provides a mask used to expose an overhang in an interposer. The mask includes a substrate, in which a first pattern is defined in a first direction and a second pattern in a second direction thereof. The first pattern is adapted for exposure of first-directional regions of the overhang, and the second pattern is adapted for exposure of second-directional regions of the overhang.

Optionally, in the mask, the first pattern and the second pattern may allow light to be shone therethrough, while the rest of the substrate other than the first pattern and the second pattern may block the light.

Optionally, in the mask, in a cross-sectional plane taken parallel to a surface of the substrate, the first pattern and the second pattern may be rectangular in shape.

Optionally, in the mask, in a cross-sectional plane taken perpendicular to a surface of the substrate, the first pattern and the second pattern may be rectangular in shape.

Optionally, in the mask, a dimension of the first pattern in the first direction may not be greater than 26 cm, and a dimension of the second pattern in the second direction may not be greater than 33 cm.

Optionally, in the mask, the first pattern and the second pattern may be arranged side by side in the first or second-direction and spaced from each other in the same direction at a distance not less than a predetermined value.

Optionally, in the mask, a single first pattern, or a plurality of first patterns arranged side by side in the second direction, and a single second pattern, or a plurality of second patterns arranged side by side in the first direction, may be defined.

The present invention also provides a mask stitching method including:
providing a first mask and a second mask, each having a size less than or equal to a maximum exposure field size of a photolithography tool;
stitching the first mask and the second mask to each other and exposing an object of interest with them, forming a target exposed region thereon;
providing a third mask including a first pattern defined in a first direction and a second pattern defined in a second direction and performing at least two exposure processes with the first pattern on the object of interest in the first direction to form a first exposed region thereon and at least two exposure processes with the second pattern on the object of interest in the second direction to form a second exposed region thereon.

Optionally, in the mask stitching method, the first mask and the second mask may be stitched so as to partially overlap each other or share a common edge.

Optionally, in the mask stitching method, the first pattern may have a width of x1 measured in the first direction and a width of y1 measured in the second direction, and the second pattern may have a width of x2 measured in the first direction and a width of y2 measured in the second direction, wherein x1 is not less than half of the sum of a width of the stitched first mask and the second mask measured in the first direction and x2, and/or y2 is not less than half of the sum of a width of the stitched first mask and the second mask measured in the second direction and y1.

Optionally, in the mask stitching method, x1 may not be greater than 26 cm, and y2 may not be greater than 33 cm.

Optionally, in the mask stitching method, the first pattern may be used to expose adjacent two regions of the object of interest in the first direction, which have a first overlap, and the second pattern may be used to expose adjacent two regions of the object of interest in the second direction, which have a second overlap.

Optionally, in the mask stitching method, the first exposed region may be located at a first side, and the second exposed region at a second side, of the target exposed region, the first side extending in the first direction, the second side extending in the second direction.

Optionally, in the mask stitching method, the first exposed region may be contiguous with the second exposed region.

Optionally, in the mask stitching method, the object of interest may be an interposer, wherein the target exposed region is formed as a die region of the interposer, which contains features to be electrically connected to a die to be wired up on the interposer, and wherein the first and second exposed regions are formed as an overhang of the interposer, which serves to provide physical support to portions of the die extending beyond the die region.

The present invention also provides an exposure method including the steps of:

Step S1: picking up a first mask and a second mask, each having a size less than or equal to a maximum exposure field size of a photolithography tool, stitching the first mask and the second mask to each other and exposing an object of interest with them, forming a target exposed region thereon; and

Step S2: picking up a third mask including a first pattern defined in a first direction and a second pattern defined in a second direction and performing at least two exposure processes with the first pattern on the object of interest in the first direction to form a first exposed region thereon and at least two exposure processes with the second pattern on the object of interest in the second direction to form a second exposed region thereon.

Optionally, in the exposure method, multiple exposure processes may be performed with the first mask and the second mask on a single or multiple regions of the object of interest simultaneously or stepwise.

Optionally, the exposure method may further include:
before step S1,
taking the first mask and the second mask out from a mask library in step S11, which is completed within a time period of T1; and
after step S1 and before step S2,
taking the third mask from the mask library in step S21, which is completed within a time period of T1,
wherein the pickup of the first mask in step S1 is completed within a time period of T21, the pickup of the second mask in step S1 within a time period of T22 and the pickup of the third mask in step S3 within a time period of T23.

Optionally, in the exposure method, steps S11, S1, S21 and S2 may be each performed for n times to expose n objects of interest, wherein T21=T22=T23=T2, and wherein the exposure of the n objects of interest is completed within a time period of 2nT1+3nT2.

Optionally, in the exposure method, steps S11 and S21 may be performed once and steps S1 and S2 for n times to expose n objects of interest, wherein T21=T22=T23=T2, and wherein the exposure of the n objects of interest is completed within a time period of 2T1+3nT2.

The present invention provides a mask, a mask stitching method and an exposure method. The mask includes a substrate, in which a first pattern is defined in a first direction and a second pattern in a second direction thereof. The first pattern is adapted for exposure of first-directional regions of the overhang, and the second pattern is adapted for exposure of second-directional regions of the overhang. With this arrangement, the overhang of the interposer can be exposed using a single mask, reducing photolithographic cost. In addition, as use of fewer masks is made possible, less effort and time is required by mask pickup. This reduces the time required by photolithographic processing, enabling more efficient photolithographic processing at even lower cost.

### BRIEF DESCRIPTION OF THE DRAWINGS

FIG. 1 shows a schematic partial view of an interposer.

FIG. 2 schematically illustrates a mask according to an embodiment of the present invention.

FIG. 3 schematically illustrates stitched first and second masks according to an embodiment of the present invention.

FIG. 4 schematically illustrates regions exposed with stitched first, second and third masks according to an embodiment of the present invention.

FIG. 5 schematically illustrates how an exposure method is implemented according to an embodiment of the present invention.

FIG. 6 schematically illustrates how an exposure method is implemented by a photolithography tool according to an embodiment of the present invention.

### LIST OF REFERENCE NUMERALS

100 interposer; 101 die region; 102 overhang; 1020 first-directional region; 1021 second-directional region;
200 mask; 201 substrate; 202 first pattern; 203 second pattern; 204 distance; 210 first mask; 220 second mask;
300 target exposed region; 310 first exposed region; 311 first overlap; 320 second exposed region; 321 second overlap;
400 robot; 401 mask library; 402 robotic hand; 403 support table.

### DETAILED DESCRIPTION

Mask, mask stitching methods and exposure methods according to particular embodiments of the present invention will be described in detail below with reference to the accompanying drawings. From the following description, advantages and features of the present invention will be more apparent. Note that the figure is provided in a very simplified form not necessarily drawn to exact scale for the only purpose of helping to explain the disclosed embodiments in a more convenient and clearer way.

The terminology used herein is for the purpose of describing particular embodiments only and is not intended to be limiting of the invention. Unless defined otherwise herein, all technical and scientific terms used herein have the same meaning as commonly understood by one of ordinary skill in the art to which the invention belongs. As used herein and in the appended claims, the terms “first,” “second,” and the like do not denote any order, quantity, or importance, but rather are used to distinguish one element from another. Likewise, the terms “a” and “an” do not denote a limitation of quantity, but rather denote the presence of at least one of the referenced items. The terms “plurality” or “several” means two or more than two. Unless defined otherwise herein, the terms “upper”, “upper layer”, “lower”, “lower layer” and/or the like are merely for ease of description, and should not be construed as being limited to a particular position, or to a particular spatial orientation. The use of “including”, “including” or the like herein is meant to encompass the elements or items listed thereafter and equivalents thereof but do not preclude the presence of other elements or items. The terms “connected”, “coupled” or the like are not restricted to physical or mechanical connections or couplings, and can include electrical connections or couplings, whether direct or indirect. As used herein and in the appended claims, the singular forms “a”, “an”, and the” are intended to include the plural forms as well, unless the context clearly indicates otherwise. It will be also understood that, as used herein, the term “and/or” includes any and all combinations of one or more of the associated listed items.

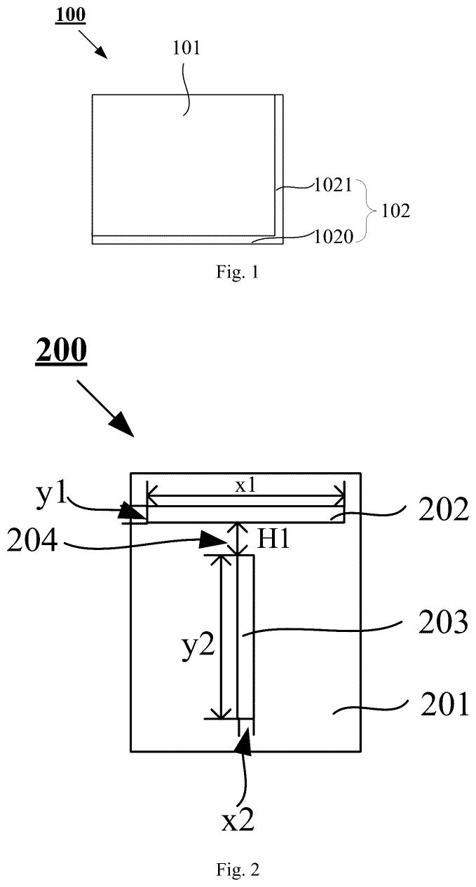

FIG. 1 shows a schematic partial view of an interposer. As shown in FIG. 1, the interposer 100 includes a die region 101 and an overhang 102. Alternatively, the interposer 100 may include multiple die regions 101, and the overhang 102 spaces adjacent die regions 101 apart. Additionally, the die regions 101 may be arranged into an array consisting of multiple rows and columns and, correspondingly, the overhang 102 may consist of first-directional regions 1020 and second-directional regions 1021. The first-directional regions 1020 may also be called row-wise regions, and the second-directional regions 1021 may also be called column-wise regions.

FIG. 2 schematically illustrates a mask according to an embodiment of the present invention. As shown in FIG. 2, the mask 200 includes a substrate 201, in which a first pattern 202 is defined in a first direction and a second pattern 203 in a second direction thereof. The first pattern 202 is used for exposure of the first-directional regions of the overhang in the interposer, and the second pattern 203 is used for exposure of the second-directional regions of the overhang in the interposer. With additional reference to FIG. 1, according to embodiments of the present application, the first pattern 202 is used for exposure of the first-directional (e.g., X-directional) regions, and the second pattern 203 is used for exposure of the second-directional (e.g., Y-directional) regions. The first pattern 202 and the second pattern 203 allow light to be shone therethrough, while the rest of the substrate 201 other than the first pattern 202 and the second pattern 203 blocks the light. According to embodiments of the present application, the first and second directions may form any angle between them. Preferably, the first and second directions intersect at right angles.

With continued reference to FIG. 2, according to embodiments of the present application, the substrate 201 may have a single first pattern 202 and a single second pattern 203. According to other embodiments of the present application, the substrate 201 may also have a plurality of first patterns 202 and a plurality of second patterns 203. Preferably, the plurality of first patterns 202 are arranged side by side in the second direction, and the plurality of second patterns 203 are arranged side by side in the first direction.

For example, the substrate 201 may have two first patterns 202, which may have different dimensions in the first direction. As another example, the substrate 201 may have three second patterns 203, which may have different dimensions in the second direction.

Preferably, in cross-sectional plane(s) taken parallel and/or perpendicular to a surface of the substrate 201, the mask 200, the first pattern 202 and the second pattern 203 are all rectangular. Long sides of the first pattern 202 extend in the first direction, and long sides of the second pattern 203 extend in the second direction. Preferably, the first-directional dimension of the first pattern 202 is not greater than 26 cm, and the second-directional dimension of the second pattern 203 is not greater than 33 cm, in order to be consistent with a maximum exposure field size of the photolithography tool used. It would be appreciated that, the mask 200, the first pattern 202 and the second pattern 203 may have any other suitable shape in the cross-sectional plane(s) taken parallel and/or perpendicular to the surface of the substrate 201, and the present application is not limited to any particular cross-sectional shape of them.

According to embodiments of the present application, the first pattern 202 and the second pattern 203 may be arranged side by side in the first or second direction and spaced from each other in the same direction at a distance not less than a predetermined value which ensures that when one of the first pattern 202 and the second pattern 203 is blocked by a blade of the photolithography tool, the other is not affected by any displacement deviation or optical edge effect of the blade. As shown in FIG. 2, the first pattern 202 may be spaced from the second pattern 203 at a distance 204, which is preferred to have a size H1 greater than or equal to the predetermined value. With this arrangement, when the first pattern 202 is being used to perform a photolithography process on the first-directional regions of the overhang in the interposer, the second pattern 203 can be blocked with the blade of the photolithography tool. Likewise, when the second pattern 203 is being used to perform a photolithography process on the second-directional regions of the overhang in the interposer, the first pattern 202 can be blocked with the blade of the photolithography tool. As the size H1 of the distance 204 is greater than or equal to the predetermined value, the processes can be avoided from being adversely affected by any displacement deviation or optical edge effect of the blade.

Embodiments of the present application also provide a corresponding mask stitching method including:
providing a first mask and a second mask, each having a size less than or equal to a maximum exposure field size of an associated photolithography tool;
stitching the first and second masks to each other and exposing an objects of interest with them, forming a target exposed region on the object of interest; and
providing a third mask including a first pattern defined in a first direction and a second pattern defined in a second direction and performing at least two exposure processes with the first pattern on the object of interest in the first direction to form a first exposed region thereon and at least two exposure processes with the second pattern on the object of interest in the second direction to form a second exposed region thereon.

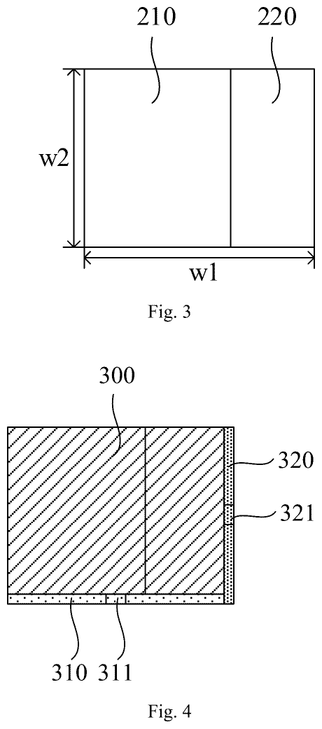

FIG. 3 shows a schematic illustration of the stitched first and second masks 210 and 220 according to an embodiment of the present application, which are used to form the target exposed region on the object of interest, for example, in order to form four high-bandwidth buffer (HBM) devices and one system-on-chip device (logic die) in a die region of an interposer. For example, the maximum exposure field size of the photolithography tool and the sizes of the first and second masks 210 and 220 may be all 26 mm×33 mm. Hereinafter, the third mask is referred to as the “mask 200”.

Preferably, the first and second masks 210 and 220 are stitched so as to partially overlap each other or share a common edge. In the embodiment of FIG. 3, a right edge of the first mask 210 is brought into coincidence with a left edge of the second mask 220. In an alternative embodiment, the right edge of the first mask 210 may be brought into coincidence with an upper edge of the second mask 220. It will be understood that the first and second masks 210 and 220 may also be stitched so that there is a partial overlap between them. In practice, the first and second masks 210 and 220 may also be stitched in any other appropriate manner to overcome the limitations of the maximum exposure field size of the photolithography tool. As shown in FIG. 4, the target exposed region 300 is formed on the object of interest, as a result of exposing the object of interest with the first and second masks 210 and 220.

With combined reference to FIGS. 2 and 3, according to embodiments of the present application, the first pattern 202 has a width x1 measured in the first direction and a width y1 measured in the second direction, and the second pattern has a width x2 measured in the first direction and a width y2 measured in the second direction. x1 is not less than half of the sum of a width w1 of the stitched first and second masks 210 and 220 measured in the first direction and x2, i.e., x1> (w1+x2)/2. Alternatively or additionally, y2 is not less than half of the sum of a width w2 of the stitched first and second masks 210 and 220 measured in the second direction and y1, i.e., y2>(w2+y1)/2. In this way, exposure with the third mask (i.e., the mask 200) is allowed to be carried out for a reduced number of times, resulting in increased exposure efficiency and lower exposure cost.

x1 is not greater than 26 cm, and y2 is not greater than 33 cm. The third mask 200 has a size less than or equal to the maximum exposure field size of the photolithography tool.

The object of interest may be a semiconductor or non-semiconductor material. For example, it may be a wafer or die. In the embodiment of FIG. 4, the object of interest is an interposer 100, and the target exposed region corresponds to a die region 101 of the interposer 100. The die region 101 contains features to be electrically connected to a die to be wired up on the interposer 100. The first and second exposed region 310 and 320 correspond to an overhang 102 of the interposer 100, which serves to provide physical support, and optionally route electrical connection, to portions of the die extending beyond the die region 101. The overhang 102 is provided to expand the area of the interposer 100 to allow it to support more dies other than the four HBM devices and SOC device.

The at least two exposure processes performed on the object of interest using the first pattern 202 in the first direction may be consecutive or more. Similarly, the at least two exposure processes performed on the object of interest using the second pattern 203 in the second direction may also be consecutive or more. That is, one or more other actions may be taken between the two exposure processes, or not. The exposure may be performed with the first pattern 202 in the first direction on two adjacent regions of the object of interest having a first overlap 311. The exposure may be performed with the second pattern 203 in the second direction on two adjacent regions of the object of interest having a second overlap 321. According to embodiments of the present application, the exposure may be performed with the mask 200 in the first direction on two adjacent regions of the overhang 102 in the interposer 100, which may be contiguous with each other, or have a first overlap 311. Additionally, the exposure may be performed with the mask 200 in the second direction on two adjacent regions of the overhang 102 in the interposer 100, which may be contiguous with each other, or have a first overlap 311, and in the second direction on two adjacent regions of the overhang 102 in the interposer 100, which also may be contiguous with each other, or have a second overlap 321. This can ensure etching throughout the overhang 102 and allow the photolithography processes to be more efficiently completed in shorter times.

With continued reference to FIG. 4, the first exposed region 310 is formed at a first side, and the second exposed region 320 at a second side, of the target exposed region 300. The first side extends in the first direction and the second side in the second direction. In one embodiment, the first exposed region 310 extends a distance of y1 from the first side of the target exposed region 300 in the second direction, and the second exposed region 320 extends a distance of x2 from the second side of the target exposed region 300 in the first direction. In another embodiment, the first exposed region 310 extends a distance of y1 in the second direction from a line spaced at a distance of a from the first side of the target exposed region 300, and the second exposed region 320 extends a distance of x2 in the first direction from a line spaced at a distance of b from the second side of the target exposed region 300, where both a and b are greater than zero. According to embodiments of the present application, the first exposed region 310 is contiguous with the second exposed region 320. According to other embodiments of the present application, the first exposed region 310 and the second exposed region 320 may have a partial overlap.

Thus, both the die region and the overhang can be exposed by stitching the first mask 210, the second mask 220 and the third mask. The exposure of the overhang may be accomplished by multiple exposure processes performed with the third mask on the first- and second-directional regions thereof.

Embodiments of the present application also provide an exposure method including the steps of:
Step S1: picking up a first mask and a second mask, each having a size less than or equal to a maximum exposure field size of an associated photolithography tool, stitching the first and second masks to each other and exposing an objects of interest with them, forming a target exposed region on the object of interest; and
Step S2: picking up a third mask including a first pattern defined in a first direction and a second pattern defined in a second direction and performing at least two exposure processes with the first pattern on the object of interest in the first direction to form a first exposed region thereon and at least two exposure processes with the second pattern on the object of interest in the second direction to form a second exposed region thereon.

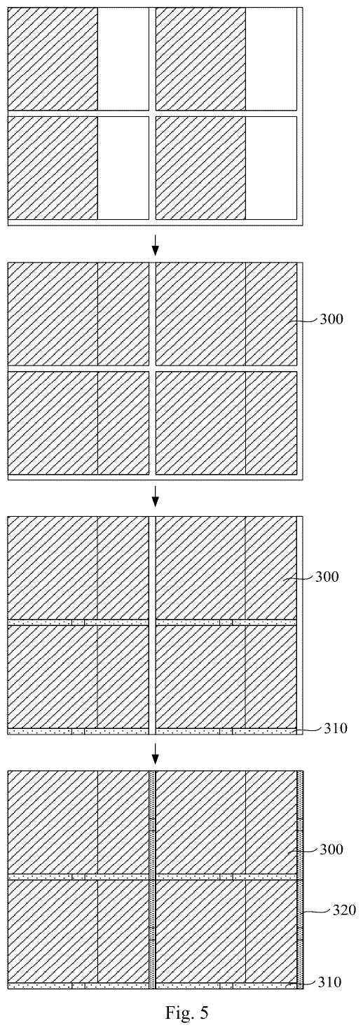

Multiple exposure processes may be performed with the first and second masks on a single or multiple regions of the object of interest simultaneously or stepwise. According to embodiments of the present application, the object of interest may be an interposer 100, and multiple exposure processes may be performed, simultaneously or stepwise, with the first and second masks on a single die region 101 or multiple die regions 101 of the interposer 100. For example, the interposer 100 may has die regions 101 arranged into an array consisting of two rows and two columns, as shown in FIG. 5. According to embodiments of the present application, the 2×2 die regions 101 may be successively exposed first with the first mask (the first step in FIG. 5) and then with the second mask (the second step in FIG. 5). According to alternative embodiments of the present application, a first one of the 2×2 die regions 101 may be exposed first with the first mask and then with the second mask. This cycle may be then successively repeated on the remaining die regions 101. The present application is not limited to any method in which the exposure is accomplished with the first and second masks.

With continued reference to FIG. 5, according to embodiments of the present application, first-directional regions 1020 corresponding to the respective four (2×2) die regions 101 are first exposed successively with the first pattern 202 in the mask 200, concurrently with the second pattern 203 being masked, thereby forming four first exposed regions 310 (the third step in FIG. 5). In particular embodiments of the present application, the first-directional regions 1020 in the first row may be first exposed, and the first-directional regions 1020 in the second row may be then exposed. In the illustrated embodiment, each first exposed region 310 is formed by two exposure processes. In other embodiments of the present application, each first exposed region 310 may be formed by more exposure processes. Each first exposed region 310 may have a first overlap 311.

Next, second-directional regions 1021 corresponding to the respective four (2×2) die regions 101 are exposed successively with the second pattern 203 in the mask 200, concurrently with the first pattern 202 being masked, thereby forming second exposed regions 320 (the fourth step in FIG. 5). In particular embodiments of the present application, the second-directional regions 1021 in the first row may be first exposed, and the second-directional regions 1021 in the second row may be then exposed. In the illustrated embodiment, each second exposed region 320 is formed by two exposure processes. In other embodiments of the present application, each second exposed region 320 may be formed by more exposure processes. Each second exposed region 320 may have a second overlap 321.

According to embodiments of the present application, the method may further include: before step S1, taking the first and second masks out from a mask library in step S11; and after step S1 and before step S2, taking the third mask from the mask library in step S21.

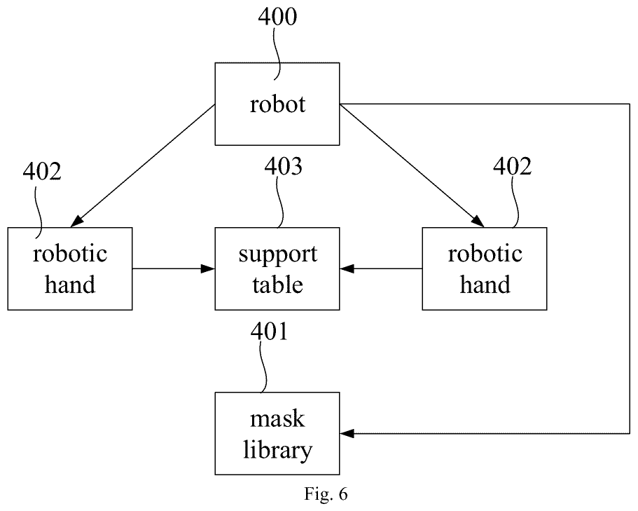

Specifically, as shown in FIG. 6, in step S11, the first and second masks 210 and 220 may be simultaneously taken out from the mask library 401 by a robot 400. Step S11 may be completed within a long time period T1.

Next, in step S1, the first and second masks 210, 220 may be picked up by a robotic hand 402 and used to expose the die regions 101 of the interposer 100. The pickup of the first mask 210 may be completed within a time period T21, and the pickup of the second mask 220 may be completed within a time period T22. T21 and T22 may be both short. That is, T1>>T21 and T1>>T22.

Subsequently, in step S21, the third mask (i.e., the mask 200) is taken out from the mask library 401 by the robot 400. Step S21 may be completed within a time period T1.

Afterwards, in step S2, the mask 200 is picked up by the robotic hand 402 to the support table 403, and the mask 200 is used to expose the overhang 102 of the interposer 100. The pickup of the mask 200 may be completed within a time period T23, and T1>>T23.

In one embodiment of the present application, n objects of interest are exposed by successively repeating steps S11, S1, S21 and S2 on each object of interest (where n is a natural number, such as 25, and the objects of interest may be interposers). Accordingly, steps S11, S1, S21 and S2 are each repeated for n times. Assuming T21=T22=T23=T2 as an example, the exposure of the n objects of interest will be completed within a time period equal to 2nT1+3nT2. For example, if n=25 and the objects of interest are interposers, then the exposure of the 25 interposers will be completed within a time period equal to 50T1+75T2. In another embodiment of the present application, the n objects of interest may be exposed first with the first and second masks and then with the third mask. In this case, the first, second and third masks need to be taken from the mask library 401 only once. That is, to expose the n objects of interest, steps S1 and S2 are repeated for n times, while steps S11 and S21 are performed only once. Thus, in the example in which T21=T22=T23=T2, the exposure of the n objects of interest will be completed within a time period equal to 2T1+3nT2. For example, if n=25 and the objects are interposers, then the exposure of the 25 interposers will be completed within a time period equal to 2T1+75T2. It would be appreciated that T21, T22 and T23 may be equal, or not.

Conventionally, objects of interest are typically exposed one by one, and the exposure of overhangs thereof usually requires the use of four masks. Accordingly, after an object of interest is exposed, it is necessary to successively carry out the steps of: taking first and second masks out from a mask library; picking up the first and second masks and exposing the next object of interest with them, forming a target exposed region (equivalent to that described herein); taking third and fourth masks out from the mask library; picking up the third and fourth masks and exposing the object with them, forming a first exposed region (equivalent to that described herein); taking fifth and sixth masks out from the mask library; and picking up the fifth and sixth masks and exposing the object with them, forming a second exposed region (equivalent to that described herein). Therefore, the exposure of n objects of interest will be completed within a time period equal to 3nT1+6nT2. If n=25 and the objects are interposers, then the exposure of the 25 interposers will be completed within a time period equal to T1*3*25+T2*6*25=75T1+150T2, where T1>>T2. Thus, the proposed exposure method can greatly reduce the time required for photolithographic processing of interposers even when they are exposed one by one, reducing cost of such processing.

Embodiments of the present invention provide a mask and a photolithography processing method for an interposer. The mask includes a substrate, in which a first pattern is defined in a first direction and a second pattern in a second direction thereof. The first pattern is used for exposure of first-directional regions of an overhang in an interposer, and the second pattern is used for exposure of second-directional regions of the overhang in the interposer. With this arrangement, the overhang of the interposer can be exposed using a single mask, reducing photolithographic cost. In addition, as use of fewer masks is made possible, less effort and time is required by mask pickup. This reduces the time required by photolithographic processing, enabling more efficient photolithographic processing at even lower cost.

As used herein, any reference to “one embodiment” or “some embodiments” means that a particular feature, structure, or characteristic described in connection with the embodiment is included in at least one embodiment or at least some embodiments disclosed herein. Therefore, the appearances of the phrase “in one embodiment” or “in some embodiments” in various places in the specification are not necessarily all referring to the same one or some embodiments. Further, in one or more embodiments, features, structures or characteristics may be combined in any suitable combination and/or sub-combination.

While a few particular embodiments of the present application have been described in detail by way of examples, those skilled in the art will understand that the foregoing examples are provided for illustration only rather than any limitation on the scope of the application. The various embodiments disclosed herein can be combined in any combination, without departing from the spirit and scope of the application. Those skilled in the art will also understand that various modifications can be made to the embodiments, without departing from the scope and spirit of the application. The scope of the application is defined by the appended claims.

1. A mask used to expose an overhang in an interposer, the mask comprising a substrate, in which a first pattern is defined in a first direction of the substrate and a second pattern in a second direction of the substrate, the first pattern adapted for exposure of first-directional regions of the overhang, the second pattern adapted for exposure of second-directional regions of the overhang.

2. The mask of claim 1, wherein the first pattern and the second pattern allow a light to be shone therethrough, while the rest of the substrate other than the first pattern and the second pattern blocks the light.

3. The mask of claim 1, wherein in a cross-sectional plane taken parallel to a surface of the substrate, the first pattern and the second pattern are rectangular in shape.

4. The mask of claim 1, wherein in a cross-sectional plane taken perpendicular to a surface of the substrate, the first pattern and the second pattern are rectangular in shape.

5. The mask of claim 1, wherein a dimension of the first pattern in the first direction is not greater than 26 cm, and a dimension of the second pattern in the second direction is not greater than 33 cm.

6. The mask of claim 1, wherein the first pattern and the second pattern are arranged side by side in the first direction or the second direction, and
wherein the first pattern and the second pattern are spaced from each other at a distance not less than a predetermined value in the first direction or the second direction.

7. The mask of claim 1, wherein a single first pattern, or a plurality of first patterns arranged side by side in the second direction, and
wherein a single second pattern, or a plurality of second patterns arranged side by side in the first direction, are defined.

8. A mask stitching method, comprising:
providing a first mask and a second mask, each having a size less than or equal to a maximum exposure field size of a photolithography tool;
stitching the first mask and the second mask to each other and exposing an object of interest with the first mask and the second mask, forming a target exposed region thereon;
providing a third mask comprising a first pattern defined in a first direction and a second pattern defined in a second direction and performing at least two exposure processes with the first pattern on the object of interest in the first direction to form a first exposed region thereon and at least two exposure processes with the second pattern on the object of interest in the second direction to form a second exposed region thereon.

9. The mask stitching method of claim 8, wherein the first mask and the second mask are stitched so as to partially overlap each other or share a common edge.

10. The mask stitching method of claim 8, wherein the first pattern has a width of x1 measured in the first direction and a width of y1 measured in the second direction, and the second pattern has a width of x2 measured in the first direction and a width of y2 measured in the second direction,
wherein x1 is not less than half of the sum of a width of the stitched first mask and the second mask measured in the first direction and x2, and/or y2 is not less than half of the sum of a width of the stitched first mask and the second mask measured in the second direction and y1.

11. The mask stitching method of claim 10, wherein x1 is not greater than 26 cm, and y2 is not greater than 33 cm.

12. The mask stitching method of claim 8, wherein the first pattern is used to expose adjacent two regions of the object of interest in the first direction, which have a first overlap, and the second pattern is used to expose adjacent two regions of the object of interest in the second direction, which have a second overlap.

13. The mask stitching method of claim 8, wherein
the first exposed region is located at a first side of the target exposed region, and the second exposed region at a second side of the target exposed region, the first side extending in the first direction, the second side extending in the second direction.

14. The mask stitching method of claim 8, wherein the first exposed region is contiguous with the second exposed region.

15. The mask stitching method of claim 8, wherein the object of interest is an interposer, wherein the target exposed region is formed as a die region of the interposer, which contains features to be electrically connected to a die to be wired up on the interposer, and wherein the first exposed region and the second exposed region are formed as an overhang of the interposer, which serves to provide physical support to portions of the die extending beyond the die region.

16. An exposure method, comprising the steps of:
step S1: picking up a first mask and a second mask, each having a size less than or equal to a maximum exposure field size of a photolithography tool, stitching the first mask and the second mask to each other and exposing an object of interest with the first mask and the second mask, forming a target exposed region thereon; and
step S2: picking up a third mask comprising a first pattern defined in a first direction and a second pattern defined in a second direction and performing at least two exposure processes with the first pattern on the object of interest in the first direction to form a first exposed region thereon and at least two exposure processes with the second pattern on the object of interest in the second direction to form a second exposed region thereon.

17. The exposure method of claim 16, wherein
multiple exposure processes are performed with the first mask and the second mask on a single or multiple regions of the object of interest simultaneously or stepwise.

18. The exposure method of claim 16,
before step S1, the exposure method further comprising step S11: taking the first mask and the second mask out from a mask library, which is completed within a time period of T1; and
after step S1 and before step S2, the exposure method further comprising
step S21: taking the third mask from the mask library, which is completed within a time period of T1,
wherein the pickup of the first mask in step S1 is completed within a time period of T21, the pickup of the second mask in step S1 within a time period of T22 and the pickup of the third mask in step S3 within a time period of T23.

19. The exposure method of claim 18, wherein steps S11, S1, S21 and S2 are each performed for n times to expose n objects of interest, wherein T21=T22=T23=T2, and wherein the exposure of the n objects of interest is completed within a time period of 2nT1+3nT2.

20. The exposure method of claim 18, wherein steps S11 and S21 are performed once and steps S1 and S2 for n times to expose n objects of interest, wherein T21=T22=T23=T2, and wherein the exposure of the n objects of interest is completed within a time period of 2T1+3nT2.
